(19) United States
(12) Patent Application Publication
(10) Pub. No.: US 2009/0291211 A1
(43) Pub. Date: Nov. 26, 2009

(54) Apparatus for atomic layer deposition and method of atomic layer deposition using the same

(75) Inventors: Myung-kwan Ryu, Yongin-si (KR); Kyung-bae Park, Seoul (KR); Sang-yoon Lee, Seoul (KR); Tae-sang Kim, Seoul (KR); Jang-yeon Kwon, Seongnam-si (KR); Byung-wook Yoo, Yongin-si (KR); Kyung-seok Son, Seoul (KR); Ji-sim Jung, Incheon (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/292,595

(22) Filed: Nov. 21, 2008

(30) Foreign Application Priority Data
May 26, 2008 (KR) 10-2008-0048676

(51) Int. Cl. C23C 16/54; B05B 3/18; B05B 1/18

(52) U.S. Cl. 427/255.23; 118/729

(57) ABSTRACT

Example embodiments provide an atomic layer deposition apparatus and a method of depositing an atomic layer using the atomic layer deposition apparatus. The atomic layer deposition apparatus may include a reaction chamber, a substrate supporter installed in the reaction chamber to support a substrate, and a shower head that is disposed above the substrate supporter and has at least one nozzle set that simultaneously inject a first source gas, a second source gas, and a purge gas onto the substrate. The method of depositing an atomic layer may include moving at least one of the substrate and the shower head in a first direction and simultaneously depositing at least one first atomic layer and at least one second atomic layer on the substrate by injecting the first source gas, the second source gas, and the purge gas through the shower head while the moving operation is performed.

### FOREIGN PRIORITY STATEMENT

This application claims priority under 35 U.S.C. §119 to Korean Patent Application No. 10-2008-0048676, filed on May 26, 2008, in the Korean Intellectual Property Office, the entire contents of which are incorporated herein by reference.

### BACKGROUND

1. Field

Example embodiments provide an apparatus for atomic layer deposition, and more specifically, an atomic layer deposition apparatus that may deposit a thin film at a higher speed and may deposit a thicker film, and a method of depositing an atomic layer using the same.

2. Description of the Related Art

Processes for manufacturing a semiconductor device or a flat panel display may include a process of depositing thin films on a substrate such as a silicon wafer or glass. An atomic layer deposition (ALD) may be used as a method of depositing a thin film, for example. The ALD method is a method of depositing a thin film having a given atomic layer thickness on a substrate which may be loaded in a reaction chamber while two different kind of source gases may be sequentially injected into the reaction chamber. The ALD method may provide a more uniform thin film of a higher quality and coatability.

More specifically, after depositing an atomic layer of a first source gas by injecting the first source gas into a reaction chamber, unreacted first source gas that is not deposited may be removed from the reaction chamber by injecting a purge gas into the reaction chamber. Afterwards, after depositing an atomic layer of a second source gas by injecting the second source gas into the reaction chamber, unreacted second source gas that is not deposited may be removed from the reaction chamber by injecting a purge gas into the reaction chamber. The atomic layer of the first source gas and the atomic layer of the second source gas may combine with each other and may form a thin film. The injection of the first source gas, purging the injection of the second source gas, and purging constitute a cycle, and a film having a given thickness and given characteristics may be formed on a substrate by repeating the above cycle.

However, according to the conventional method of depositing an atomic layer, since each of the atomic layers is sequentially deposited, a considerable amount of time may be required to obtain a film having a given thickness, and productivity may be reduced.

### SUMMARY

Example embodiments provide an atomic layer deposition apparatus that may more rapidly deposit a film having a given thickness on a substrate by simultaneously injecting a first source gas, a first purge gas, a second source gas, and a second purge gas while moving the substrate or shower head, and a method of depositing an atomic layer using the atomic layer deposition apparatus.

Example embodiments provide an atomic layer deposition apparatus that may include a reaction chamber, a substrate supporter in the reaction chamber configured to support a substrate, and a shower head disposed above the substrate supporter and including at least one nozzle set configured to simultaneously inject a first source gas, a second source gas, and a purge gas onto the substrate, wherein at least one of the substrate supporter and the shower head is movable in a first direction, and at least one of the nozzle sets includes at least one first source gas injection nozzle arranged in a first row, at least one purge gas injection nozzle arranged in a second row, at least one second source gas injection nozzle arranged in a third row, and at least one purge gas injection nozzle arranged in a fourth row, wherein the first row, the second row, the third row, and the fourth row extend parallel to each other in a direction perpendicular to the first direction.

The first row, the second row, the third row, and the fourth row may have lengths equal to or greater than a width direction length of the substrate perpendicular to the first direction.

The shower head may include a plurality of nozzle sets sequentially arranged in the first direction. The number of nozzle sets included on the shower head may correspond to the thickness of the film to be deposited on the substrate.

At least one of the first source gas injection nozzles arranged in the first row may include a plurality of first source gas injection nozzles arranged apart from each other by a given distance along the first row, at least one of the purge gas injection nozzles arranged in the second row may include a plurality of purge gas injection nozzles arranged apart from each other by a given distance along the second row, at least one of the second source gas injection nozzles arranged in the third row may include a plurality of second source gas injection nozzles arranged apart from each other by a given distance along the third row, and at least one of the purge gas injection nozzles arranged in the fourth row may include a plurality of purge gas injection nozzles arranged apart from each other by a given distance along the fourth row.

At least one of the first source gas injection nozzles, at least one of the second source gas injection nozzles, and at least one of the purge gas injection nozzles may have a slit shape extending in a direction perpendicular to the first direction.

The shower head may comprise at least one dummy nozzle next to the fourth row of at least one of the nozzle sets, and the at least one dummy nozzle may be configured to inject the first source gas parallel to the fourth row.

The shower head may include a first source gas supply line configured to supply the first source gas to at least one of the first source gas injection nozzles, a second source gas supply line configured to supply the second source gas to at least one of the second source gas injection nozzles, and a purge gas supply line configured to supply the purge gas to at least one of the purge gas injection nozzles in the shower head.

The first source gas supply line, the second source gas supply line, and the purge gas supply line may be separated from each other.

The first source gas supply line may include a first source gas main line connected to a first source gas storage tank provided outside of the reaction chamber and at least one first source gas branch line which is branched from the first source gas main line and connected to at least one of the first source gas injection nozzles, the second source gas supply line may include a second source gas main line connected to a second source gas storage tank provided outside of the reaction chamber and at least one second source gas branch line which is branched from the second source gas main line and connected to at least one of the second source gas injection nozzles, and the purge gas supply line may include a purge gas main line connected to a purge gas storage tank provided outside of the reaction chamber and at least one purge gas branch line which is branched from the purge gas main line and connected to at least one of the purge gas injection nozzles.

The shower head may be fixed and the substrate supporter may be movable in the first direction. Further, the shower head and the substrate supporter may both be movable in the first direction.

The substrate supporter may include a heating element configured to heat the substrate to a given temperature.

The reaction chamber may include an exhaust hole connected to a vacuum pump.

Example embodiments of a method of depositing a film having a given thickness and including at least a first atomic layer formed of a first source gas and at least a second atomic layer formed of a second source gas on a substrate, may include a first moving operation where at least one of the substrate and a shower head is moved in a first direction, and a first deposition operation where the first source gas, the second source gas, and the purge gas are injected through the shower head so as to simultaneously deposit at least one first atomic layer and at least one second atomic layer on the substrate while the first moving operation is performed.

The first deposition operation may be performed from an end of the substrate to an opposite end.

The first deposition operation may include a first operation of depositing the first atomic layer on the substrate by injecting the first source gas onto the substrate, a second operation of removing the first source gas by injecting the purge gas while the first operation is performed, a third operation of depositing the second atomic layer on the first atomic layer by injecting the second source gas while the first and second operations are performed, and a fourth operation of removing the second source gas by injecting the purge gas while the first, second, and third operations are performed.

The first through fourth operations may be continuously and repeatedly performed while the first moving operation is performed.

At least one of the substrate and the shower head may be returned to a given position after the first deposition operation is completed.

The first moving operation, the deposition operation, and the returning operation may be repeatedly performed.

After the first deposition operation is completed, the method may further include a second moving operation where at least one of the substrate and the shower head is moved in a second direction opposite to the first direction, and a second deposition operation where at least one first atomic layer and at least one second atomic layer is deposited while the second moving operation is performed.

The first moving operation, the first deposition operation, the second moving operation, and the second deposition operation may be repeatedly performed.

The shower head may be fixed and the substrate may be moved in the first direction.

### BRIEF DESCRIPTION OF THE DRAWINGS

The above and other features and advantages of example embodiments will become more apparent by describing them in detail with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a cross-sectional view of an atomic layer deposition apparatus according to example embodiments.

FIG. 2A is a cross-sectional view of a nozzle set provided on the shower head of FIG. 1.

FIG. 2B is a simplified perspective view of the nozzle set provided on the shower head of FIG. 1.

FIGS. 2C and 2D are perspective views of modified versions of the nozzle set of FIG. 2B.

FIGS. 3A through 3C are cross-sectional views illustrating the formation of a film on a substrate by moving the substrate in a direction according to example embodiments of a method using the atomic layer deposition apparatus of FIG. 1.

FIG. 4 is a cross-sectional view of a modified version of the shower head of FIG. 2A.

FIGS. 5A and 5B are cross-sectional views illustrating the formation of a film on a substrate by reciprocally moving the substrate using the shower head of FIG. 4.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

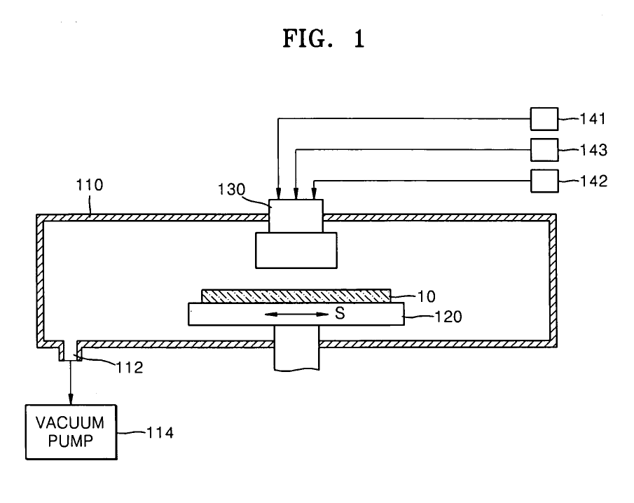

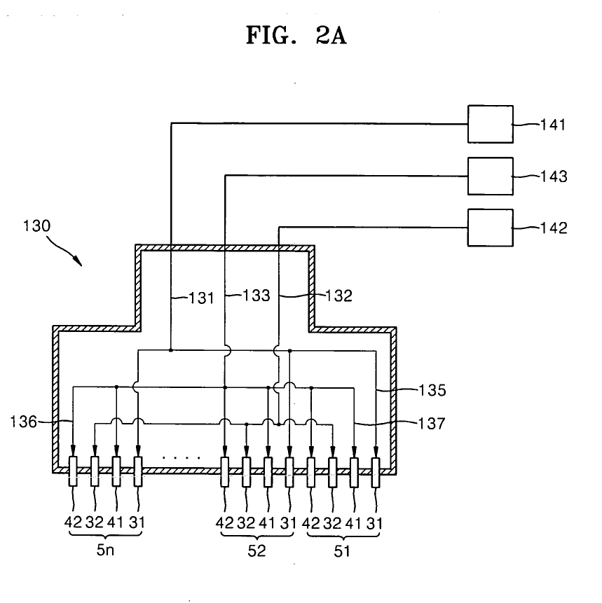

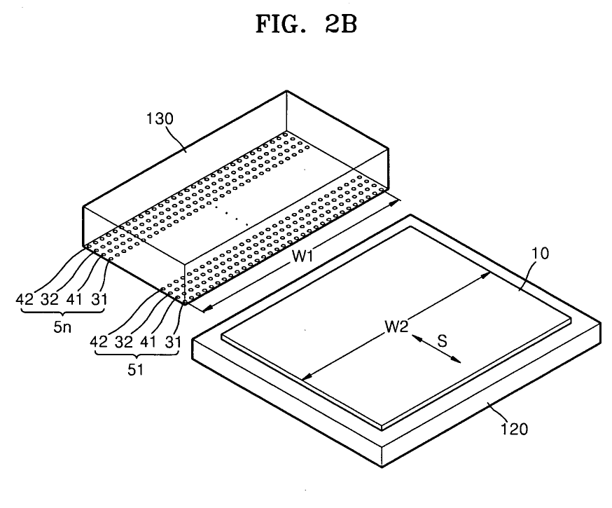

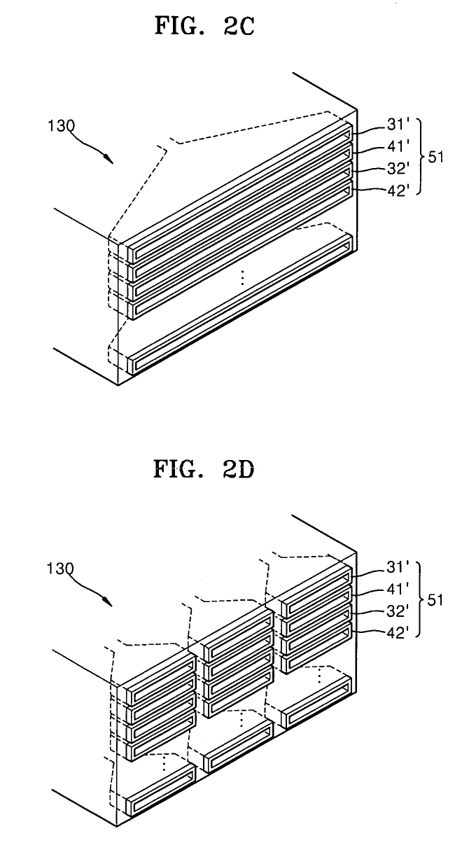

FIG. 1 is a cross-sectional view of an atomic layer deposition apparatus according to example embodiments. FIG. 2A is a cross-sectional view of a nozzle set provided on the shower head of FIG. 1, and FIG. 2B is a perspective view of the nozzle set provided on the shower head of FIG. 1.

Referring to FIGS. 1, 2A, and 2B, an atomic layer deposition apparatus may include a reaction chamber 110, a substrate supporter 120 installed in the reaction chamber 110 to support a substrate 10, and a shower head 130 disposed above the substrate supporter 120 to inject a first source gas, a second source gas, and a purge gas.

The inside of the reaction chamber 110 may be maintained in a vacuum state. For this purpose, an exhaust hole 112 may be formed on a wall of the reaction chamber 110 and may be connected to a vacuum pump 114. The exhaust hole 112 may be used for discharging the first source gas, the second source gas, and the purge gas.

The substrate supporter 120 may be installed on a lower side of the reaction chamber 110 to support the substrate 10. A heating element (not shown) for heating the substrate 10 to a given temperature may be provided in or around the substrate supporter 120.

At least one of the substrate supporter 120 and the shower head 130 may be installed to reciprocally move along a scanning direction S. For example, only the substrate supporter 120 may be movably installed or only the shower head 130 may be movably installed. Also, the substrate supporter 120 and the shower head 130 may be installed to move relative to each other. For clarity, example embodiments where the substrate supporter 120 is movably installed will be described.

The shower head 130 may include at least one nozzle set 51, 52, or 5n that can simultaneously inject the first source gas, the second source gas, and the purge gas onto the substrate 10. At least one of the nozzle sets 51, 52, and 5n may include a plurality of nozzles 31, 41, 32, and 42 arranged along four rows which extend parallel to each other in a perpendicular direction to the moving direction S of the substrate supporter 120. The four rows may be disposed apart from each other by a given distance. A plurality of first source gas injection nozzles 31 that inject the first source gas may be arranged along the first row of the four rows. A plurality of purge gas injection nozzles 41 that inject the purge gas for removing remaining first source gas may be arranged along the second row of the four rows. A plurality of second source gas injection nozzles 32 that inject the second source gas may be arranged along the third row of the four rows. A plurality of purge gas injection nozzles 42 that inject the purge gas for removing remaining second source gas may be arranged along the fourth row of the four rows.

The first row, the second row, the third row, and the fourth row may have a length W1 equal to or greater than a width direction length W2 of the substrate 10. The width direction length W2 may be perpendicular to the scanning direction so that the above gases can be uniformly injected onto the entire width direction of the substrate 10.

The first source gas injection nozzles 31 arranged in the first row, the purge gas injection nozzles 41 arranged in the second row, the second source gas injection nozzles 32 arranged in the third row, and the purge gas injection nozzles 42 arranged in the fourth row may constitute one nozzle set 51, 52, or 5n. Only one nozzle set 51, 52, or 5n may be disposed on the shower head 130. Also, as shown in FIGS. 2A and 2B, the shower head 130 may include a plurality of nozzle sets 51, 52, and 5n sequentially disposed along the moving direction S. The number of nozzle sets 51, 52, and 5n included on shower head 130 may correspond to the thickness of a film to be deposited on the substrate 10, for example.

A first source gas supply line 131 and 135 for supplying the first source gas to the first source gas injection nozzles 31, a second source gas supply line 132 and 136 for supplying the second source gas to the second source gas injection nozzles 32, and a purge gas supply line 133 and 137 for supplying the purge gas to the purge gas injection nozzles 41 and 42 may be provided in the shower head 130. The first source gas supply line 131 and 135, the second source gas supply line 132 and 136, and the purge gas supply line 133 and 137 may be separately disposed so that the gasses are not mixed with each other.

A first source gas storage tank 141, a second source gas storage tank 142, and a purge gas storage thank 143 may be provided on an outside of the reaction chamber 110. The first source gas supply line 131 and 135 may include one first source gas main line 131 connected to the first source gas storage tank 141 and may further include a plurality of first source gas branch lines 135 which are branched from the first source gas main line 131 and connected to the first source gas injection nozzles 31. If a plurality of nozzle sets 51, 52, and 5n are provided on the shower head 130, the first source gas branch lines 135 may be connected to the first source gas injection nozzles 31 included in the nozzle sets 51 52, and 5n, respectively.

The second source gas supply line 132 and 136 may include a second source gas main line 132 connected to the second source gas storage tank 142 and a plurality of second source gas branch lines 136 which may be branched from the second source gas main line 132 and connected to the second source gas injection nozzles 32. If a plurality of nozzle sets 51, 52, and 5n are provided on the shower head 130, the second source gas branch lines 136 may be connected to the second source gas injection nozzles 32 included in the nozzle sets 51, 52, and 5n, respectively.

Also, the purge gas supply line 133 and 137 may include a purge gas main line 133 connected to the purge gas storage tank 143 and a plurality of purge gas branch lines 137 which may be branched from the purge gas main line 133 and connected to the purge gas injection nozzles 41 and 42 arranged in the second and fourth rows, respectively. If a plurality of nozzle sets 51, 52, and 5n are provided on the shower head 130, the purge gas branch lines 137 may be connected to the purge gas injection nozzles 41 and 42 included in the nozzle sets 51, 52, and 5n, respectively.

According to example embodiments of the shower head 130, the first source gas, the second source gas, and the purge gas may not be mixed with each other in the shower head 130, and may be injected onto the substrate 10 through the nozzles 31, 41, 32, and 42, respectively.

FIGS. 2C and 2D are perspective views of the nozzle set of FIG. 2B according to example embodiments.

Referring to FIGS. 2C and 2D, nozzles 31′, 41′, 32′, and 42′ included in at least one nozzle set 51 provided in the shower head 130 may have a slit shape extending in a perpendicular direction with respect to the moving direction S.

For example, one first source gas injection nozzle 31′ having a slit shape may be arranged in the first row, one second source gas injection nozzle 32′ having a slit shape may be arranged in the third row, and each of the purge gas injection nozzles 41′ and 42′ having a slit shape may be arranged in the second and fourth rows, as shown in FIG. 2C. In this example embodiment, each of the nozzles 31′, 41′, 32′, and 42′ having a slit shape may have a length equal to or greater than a width direction length W2 of the substrate 10, which is perpendicular to the moving direction S.

Additional example embodiments provide that, a plurality of first source gas injection nozzles 31′ having a slit shape may be arranged apart from each other by a given distance in the first row, a plurality of second source gas injection nozzles 32′ having a slit shape may be arranged apart from each other by a given distance in the third row, and a plurality of purge gas injection nozzles 41′ and 42′ having a slit shape may be arranged apart from each other by a given distance in the second and fourth rows, as shown in FIG. 2D.

Operation of an atomic layer deposition apparatus according to example embodiments may allow at least one first atomic layer formed of a first source gas and at least one second atomic layer formed of a second source gas to be simultaneously deposited on the substrate 10 by injecting the first source gas, the second source gas, and the purge gas through the shower head 130 while moving at least one of the substrate 10 and the shower head 130.

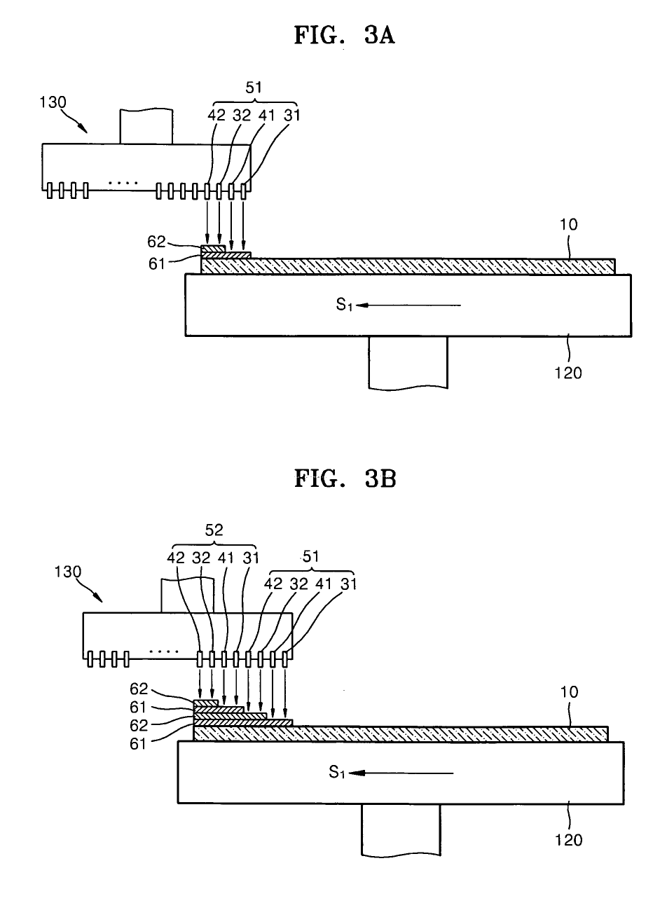

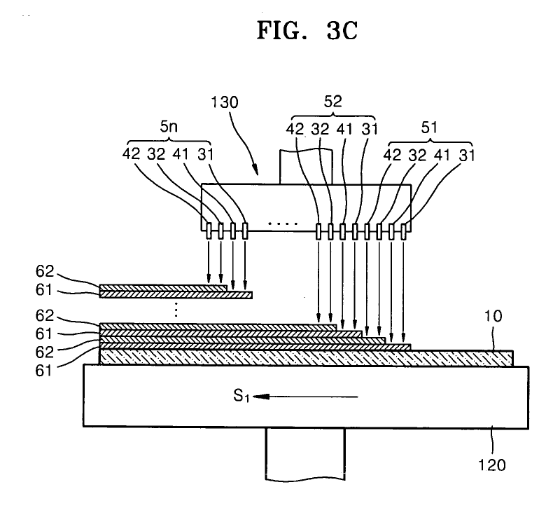

FIGS. 3A through 3C are cross-sectional views illustrating example embodiments of forming a film on a substrate by moving the substrate in a direction using the atomic layer deposition apparatus shown in FIG. 1.

Referring to FIG. 3A, a method of depositing an atomic layer according to example embodiments may include moving at least one of the substrate 10 and the shower head 130 in a first direction S1, and simultaneously depositing at least one first atomic layer 61 and at least one second atomic layer 62 on the substrate 10 by injecting the first source gas, the second source gas, and the purge gas through the shower head 130 while the moving operation is performed.

The first atomic layer 61 and the second atomic layer 62 deposited on the substrate 10 may form a film having a given thickness by reacting with each other.

The deposition of the film may be performed while the substrate 10 is moving, and thus, the deposition of the film may be achieved from an end to the other end of the substrate 10.

In the moving operation, the substrate supporter 120 that supports the substrate 10 may be moved in the first direction S1.

The deposition operation may include first through fourth operations as follows. While moving the substrate 10 in the first direction S1, the first atomic layer 61 may be deposited on the substrate 10 by injecting the first source gas through the first source gas injection nozzles 31, which may be arranged in the first row of the first nozzle set 51 provided on the shower head 130 (the first operation). While the first operation is performed, remaining first source gas may be removed by injecting the purge gas through the purge gas injection nozzles 41, which may be arranged in the second row of the first nozzle set 51 (the second operation). While the first and second operations are performed, the second atomic layer 62 may be deposited on the first atomic layer 61 by injecting the second source gas onto the first atomic layer 61 through the second source gas injection nozzles 32, which may be arranged in the third row of the first nozzle set 51 (the third operation). Next, while the first through third operations are performed, remaining second source gas may be removed by injecting the purge gas through the purge gas injection nozzles 42, which may be arranged in the fourth row of the first nozzle set 51 (the fourth operation).

For example, one first nozzle set 51 may be provided on the shower head 130, and when the deposition operation comprising the first through fourth operations is completed, a thin film comprising one first atomic layer 61 and one second atomic layer 62 may be formed on the substrate 10.

In this example embodiment, the depositions of the first atomic layer 61 and the second atomic layer 62 may be simultaneously performed. Thus, a film having a desired thickness may be formed in a shorter time compared to a conventional method in which the second atomic layer 62 is deposited after the first atomic layer 61 is deposited.

When the above deposition operations are completed, a returning operation may be performed to return at least one of the substrate 10 and the shower head 130 to a given position, and afterwards, another moving operation and the deposition operation may be performed. That is, the moving operation, the deposition operation, and the returning operation may be repeatedly performed, and in this case, a thicker film may be formed in a shorter period of time.

The shower head 130 may include a plurality of nozzle sets 51, 52, and 5n. In each of the moving operations of the substrate 10, that is, while the substrate 10 moves one time in the first direction S1, the deposition operation comprising the first through fourth operation may be repeatedly and continuously performed.

More specifically, the first atomic layer 61 and the second atomic layer 62 may be deposited on the substrate 10 by injecting the first source gas, the second source gas, and the purge gas through the nozzles 31, 41, 32, and 42 included in the first nozzle set 51.

Next, as shown in FIG. 3B, the first atomic layer 61 and the second atomic layer 62 may be re-deposited on the second atomic layer 62, which is already deposited by injecting the first source gas, the second source gas, and the purge gas through the nozzles 31, 41, 32, and 42 included in the second nozzle set 52.

The depositions of the first atomic layer 61 and the second atomic layer 62 by the first nozzle set 51 and the depositions of the first atomic layer 61 and the second atomic layer 62 by the second nozzle set 52 may be simultaneously performed.

Further, the depositions of the first atomic layer 61 and the second atomic layer 62 by the next nozzle set may be performed.

As shown in FIG. 3C, the first atomic layer 61 and the second atomic layer 62 may be deposited on the substrate 10 by injecting the first source gas, the second source gas, and the purge gas through the nozzles 31, 41, 32, and 42 included in the last nozzle set 5n. Then, a thicker film, in which a plurality of first atomic layers 61 and second atomic layers 62 are alternately deposited, may be formed on the substrate 10.

According to example embodiments, a thicker film may be formed on the substrate 10 by repeatedly and continuously performing the deposition operation while the substrate 10 moves one time in the first direction S1.

When deposition operations are completed, a returning operation may be performed to return the substrate 10 to the original position, and another moving operation and the deposition operation may be performed. That is, a thicker film can be formed by repeatedly performing the moving operation, the deposition operation, and the returning operation. Thus, a method of depositing an atomic layer according to example embodiments may be applied to a process of forming a film having a few thousand of A, such as an LCD manufacturing process, for example.

The number of nozzle sets 51, 52, and 5n included on the shower head 130 may correspond to the thickness of a film to be deposited on the substrate 10. Thus, a film having a given thickness may be formed while the substrate 10 moves one time.

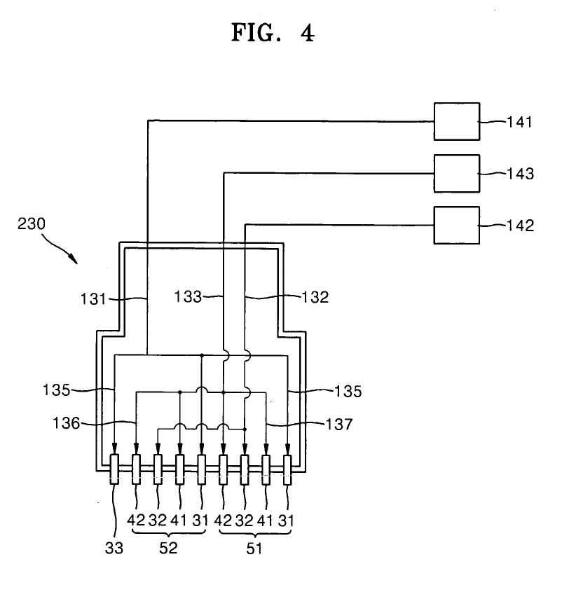

FIG. 4 is a cross-sectional view of a modified version of the shower head 130 of FIG. 2A.

Referring to FIG. 4, in a shower head 230, a plurality of dummy nozzles 33 for injecting the first source gas may be arranged parallel to the fourth row next to the fourth row of at least one of the nozzle sets 51 and 52. In FIG. 4, it is shown that the shower head 230 includes two nozzle sets 51 and 52 and the dummy nozzles 33, however, example embodiments of shower head 230 are not limited thereto. That is, the shower head 230 may include one nozzle set 51 and a plurality of dummy nozzles 33, or may include more than three nozzle sets and a plurality of dummy nozzles 33, for example. Each of the dummy nozzles 33 may be connected to the first source gas branch line 135 described above.

The dummy nozzles 33 may be used to form a film on the substrate 10 by reciprocally moving the substrate 10.

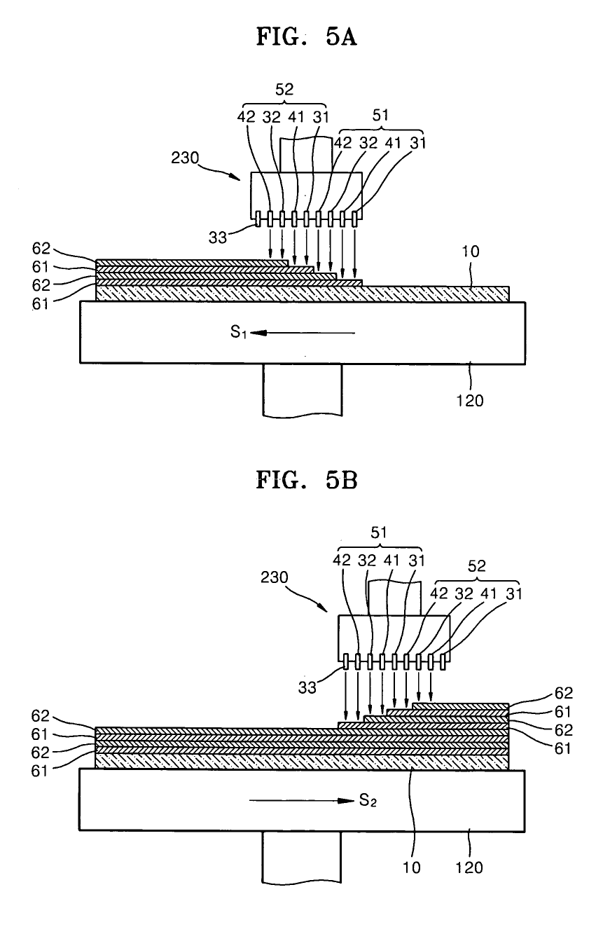

FIGS. 5A and 5B are cross-sectional views illustrating example embodiments of formation of a film on a substrate by reciprocally moving the substrate using the shower head 230 of FIG. 4.

Referring to FIG. 5A, a first operation of moving the substrate 10 in the first direction S1 may be performed. While the first operation of moving the substrate 10 is performed, a first operation of simultaneously depositing the first atomic layer 61 and the second atomic layer 62 using the first nozzle set 51 and the second nozzle set 52 of the shower head 230 may be performed. At this point, the first source gas may not be injected through the dummy nozzles 33. The first moving operation and the first deposition operation may be identical to the moving operation and the deposition operation described with reference to FIGS. 3A through 3C, and for clarity the description thereof will not be repeated.

Referring to FIG. 5B, when the first deposition operation is completed, a second operation of moving the substrate 10 in a second direction S2, which may be an opposite direction of the first direction S1, may be performed. While the second moving operation is performed, a second operation of depositing at least one first atomic layer 61 and at least one second atomic layer 62 on the previously deposited second atomic layer 62 may be performed. At this point, the first source gas may be injected onto the substrate 10 through the dummy nozzles 33, and the first source gas may not be injected through the first source gas injection nozzles 31 arranged in the first row of the first nozzle set 51. Thus, the dummy nozzles 33 may act as the first source gas injection nozzles 31, and thus, the dummy nozzles 33, the purge gas injection nozzles 42 arranged in the fourth row of the second nozzle set 52, the second source gas injection nozzles 32 arranged in the third row of the second nozzle set 52, and the purge gas injection nozzles 41 arranged in the second row of the second nozzle set 52 may constitute another new nozzle set.

According to example embodiments of the method of depositing an atomic layer, a plurality of first atomic layers 61 and a plurality of second atomic layers 62 may be deposited on the substrate 10 while the substrate 10 is reciprocally moved, and a film having a given thickness may be more rapidly formed on the substrate 10.

Also, the first moving operation, the first deposition operation, the second moving operation, and the second deposition operation may be repeatedly performed, and thus, a thicker film may be deposited on the substrate 10.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. An atomic layer deposition apparatus comprising:
a reaction chamber,
a substrate supporter in the reaction chamber configured to support a substrate, and
a shower head disposed above the substrate supporter and including at least one nozzle set configured to simultaneously inject a first source gas, a second source gas, and a purge gas onto the substrate, wherein
at least one of the substrate supporter and the shower head is movable in a first direction, and
at least one of the nozzle sets includes at least one first source gas injection nozzle arranged in a first row, at least one purge gas injection nozzle arranged in a second row, at least one second source gas injection nozzle arranged in a third row, and at least one purge gas injection nozzle arranged in a fourth row,
wherein the first row, the second row, the third row, and the fourth row extend parallel to each other in a direction perpendicular to the first direction.

2. The atomic layer deposition apparatus of claim 1; wherein the first row, the second row, the third row, and the fourth row have lengths equal to or greater than a width direction length of the substrate perpendicular to the first direction.

3. The atomic layer deposition apparatus of claim 1, wherein the shower head includes a plurality of nozzle sets sequentially arranged in the first direction.

4. The atomic layer deposition apparatus of claim 3, wherein the number of nozzle sets included on the shower head corresponds to the thickness of the film to be deposited on the substrate.

5. The atomic layer deposition apparatus of claim 1, wherein
at least one of the first source gas injection nozzles arranged in the first row includes a plurality of first source gas injection nozzles arranged apart from each other by a given distance along the first row,
at least one of the purge gas injection nozzles arranged in the second row includes a plurality of purge gas injection nozzles arranged apart from each other by a given distance along the second row,
at least one of the second source gas injection nozzles arranged in the third row includes a plurality of second source gas injection nozzles arranged apart from each other by a given distance along the third row, and
at least one of the purge gas injection nozzles arranged in the fourth row includes a plurality of purge gas injection nozzles arranged apart from each other by a given distance along the fourth row.

6. The atomic layer deposition apparatus of claim 1, wherein at least one of the first source gas injection nozzles, at least one of the second source gas injection nozzles, and at least one of the purge gas injection nozzles have a slit shape extending in a direction perpendicular to the first direction.

7. The atomic layer deposition apparatus of claim 1, wherein
the shower head comprises at least one dummy nozzle next to the fourth row of at least one of the nozzle sets, and
the at least one dummy nozzle is configured to inject the first source gas parallel to the fourth row.

8. The atomic layer deposition apparatus of claim 1, wherein the shower head includes
a first source gas supply line configured to supply the first source gas to at least one of the first source gas injection nozzles,
a second source gas supply line configured to supply the second source gas to at least one of the second source gas injection nozzles, and
a purge gas supply line configured to supply the purge gas to at least one of the purge gas injection nozzles in the shower head.

9. The atomic layer deposition apparatus of claim 8, wherein the first source gas supply line, the second source gas supply line, and the purge gas supply line are separated from each other.

10. The atomic layer deposition apparatus of claim 8, wherein
the first source gas supply line includes a first source gas main line connected to a first source gas storage tank provided outside of the reaction chamber and at least one first source gas branch line which is branched from the first source gas main line and connected to at least one of the first source gas injection nozzles,
the second source gas supply line includes a second source gas main line connected to a second source gas storage tank provided outside of the reaction chamber and at least one second source gas branch line which is branched from the second source gas main line and connected to at least one of the second source gas injection nozzles, and
the purge gas supply line includes a purge gas main line connected to a purge gas storage tank provided outside of the reaction chamber and at least one purge gas branch line which is branched from the purge gas main line and connected to at least one of the purge gas injection nozzles.

11. The atomic layer deposition apparatus of claim 1, wherein the shower head is fixed and the substrate supporter is movable in the first direction.

12. The atomic layer deposition apparatus of claim 1, wherein the shower head and the substrate supporter are movable in the first direction.

13. A method of depositing a film having a given thickness and including at least a first atomic layer formed of a first source gas and at least a second atomic layer formed of a second source gas on a substrate, comprising:
a first moving operation where at least one of the substrate and a shower head is moved in a first direction, and
a first deposition operation where the first source gas, the second source gas, and the purge gas are injected through the shower head so as to simultaneously deposit at least one first atomic layer and at least one second atomic layer on the substrate while the first moving operation is performed.

14. The method of claim 13, wherein the first deposition operation is performed from an end of the substrate to an opposite end.

15. The method of claim 13, wherein the first deposition operation includes
a first operation of depositing the first atomic layer on the substrate by injecting the first source gas onto the substrate,
a second operation of removing the first source gas by injecting the purge gas while the first operation is performed,
a third operation of depositing the second atomic layer on the first atomic layer by injecting the second source gas while the first and second operations are performed, and
a fourth operation of removing the second source gas by injecting the purge gas while the first, second, and third operations are performed.

16. The method of claim 15, wherein the first through fourth operations are continuously and repeatedly performed while the first moving operation is performed.

17. The method of claim 13, further including returning at least one of the substrate and the shower head to a given position after the first deposition operation is completed.

18. The method of claim 17, wherein the first moving operation, the deposition operation, and the returning operation are repeatedly performed.

19. The method of claim 13, after the first deposition operation is completed, further including
a second moving operation where at least one of the substrate and the shower head is moved in a second direction opposite to the first direction, and
a second deposition operation where at least one first atomic layer and at least one second atomic layer is deposited while the second moving operation is performed.

20. The method of claim 19, wherein the first moving operation, the first deposition operation, the second moving operation, and the second deposition operation are repeatedly performed.

21. The method of claim 13, wherein the shower head is fixed and the substrate is moved in the first direction.
